(19) United States
(12) Patent Application Publication
(10) Pub. No.: US 2015/0289599 A1
(43) Pub. Date: Oct. 15, 2015

(54) ELECTRONIC EQUIPMENT STORAGE CASE

(71) Applicant: Junichi UCHIDA, Tokyo (JP)

(72) Inventor: Junichi UCHIDA, Tokyo (JP)

(73) Assignee: Junichi UCHIDA, Tokyo (JP)

(21) Appl. No.: 14/389,773

(22) PCT Filed: May 9, 2012
(86) PCT No.: PCT/JP2012/061853

§ 371 Date: Nov. 6, 2014

(30) Foreign Application Priority Data
Apr. 4, 2012 (JP) 2012-085372

(51) Int. Cl. A44B 11/00; H05K 5/00; H05K 5/02; A44B 11/04

(52) U.S. Cl. CPC A44B 11/005; A44B 11/04; H05K 5/0086; H05K 5/0204

(57) ABSTRACT

There is provide an electronic device storage case allowing a user to easily store or take out an electronic device such as a smartphone without giving feeling of bulge to the user.

An electronic device storage case includes a storage part 12 which stores an electronic device 1; and wing parts 16A, 16B which are formed on both sides of the storage part 12 and attach the storage part 12 to a band-shaped member 14, wherein the wing parts 16A, 16B are formed with pass-through parts 18A, 18B through which the band-shaped member 14 is passed, respectively. The storage part 12 and the wing parts 16A, 16B are continuously formed, thereby making it possible to suppress the feeling of bulge of the storage part 12.

### TECHNICAL FIELD

The present invention relates to an electronic equipment storage case attachable, for example, to a belt or the like.

### BACKGROUND ART

Conventionally, various cases for storing a cellular phone have been proposed.

For example, the following Patent Document 1 discloses a case for a cellular phone set which is composed of a housing case body for housing the cellular phone set and a fitting part for fitting the housing case body to a belt of clothing in an attachable/detachable manner and in which the housing case body is held at the fitting part in the state of being tilted from a direction vertical to the belt.

On the other hand, the following Patent Document 2 discloses a portable telephone-carrying band which is composed of a ring-shape sheet which is formed by joining both the ends of a band-shape sheet made of a stretch material such as rubber, wherein a bag-shape pocket for holding the portable telephone is formed on a part of the ring-shape sheet, so that the ring-shape sheet is attached to an arm or a leg of a user by utilizing its stretchability to be used.

### PRIOR ART DOCUMENT

### Patent Document

Patent document 1: Japanese Patent Application Laid-open No. 2005-177110

Patent document 2: Japanese Patent Application Laid-open No. 2002-194610

Patent document 3: Japanese Patent Application Laid-open No. 2008-259786

Patent document 4: Japanese Patent Application Laid-open No. 2009-114552

Patent document 5: Japanese Patent Application Laid-open No. H10-26350

Patent document 6: Japanese Registered Utility Model No. 3067781

Patent document 7: Japanese Registered Utility Model No. 3173262

### DISCLOSURE OF THE INVENTION

### Problems to be Solved by the Invention

However, in the case for a cellular phone set of the above Patent Document 1, only the housing case body is structured in a shape bulging outside, so that when it is attached to the belt, only a portion of the housing case body greatly protrudes. Therefore, the feeling of bulge is emphasized to deteriorate design which is hard to be accepted, in particular, by young generation. Further, even when the housing case is hidden behind a shirt, the shirt greatly protrudes at only the portion of the housing case and looks bad.

Besides, in the portable telephone-carrying band of the above Patent Document 2, the pocket is formed inside the band and thus rarely gives an impression that the pocket bulges outside when the portable telephone-carrying band is fitted on the body, but the pocket dents on the body side and presses the body to deteriorate feeling of fitting. Further, the state where the pocket dents on the body side causes a problem of making an storage action or a taking-out action of the portable telephone difficult.

Hence, in consideration of the above problems, an object of the present invention is to provide an electronic device storage case allowing a user to easily store or take out an electronic device such as a smartphone without giving feeling of bulge to the user.

### Means for Solving the Problems

The present invention includes:

a storage part which stores an electronic device; and

wing parts which are formed on both sides of the storage part and attach the storage part to a band-shaped member,

wherein the wing parts are formed with pass-through parts through is which the band-shaped member is passed.

In this case, it is preferable that in a state where the band-shaped member is passed through the pass-through parts and the band-shaped member is curved at a predetermined curvature, the wing parts connect a surface part of the storage part to a surface part of the band-shaped member by a flat surface or a curved surface.

In this case, it is preferable that the storage part has a surface part, and the surface part has a facing part which faces the electronic device stored in the storage part and connection parts which connect the facing part with surface parts of the wing parts.

In this case, it is preferable that in a state where the electronic device is stored in the storage part, the connection parts tilt with respect to the facing part.

In this case, it is preferable that the surface part of the storage part and the surface parts of the wing parts are composed of the same member which extends from the surface part of the storage part to the surface parts of the wing parts.

In this case, it is preferable that adjustment members for adjusting a positional relationship between the wing parts and the pass-through parts are provided between the wing parts and the pass-through parts.

### Effect of the Invention

According to the present invention, an electronic device storage case includes: a storage part which stores an electronic device; and a pair of wing parts which are formed on both sides of the storage part and attach the storage part to a band-shaped member, wherein the wing parts are formed with pass-through parts through which the band-shaped member is passed, so that it is possible to easily store the electronic device into the storage part or easily take out the electronic device stored in the storage part.

Further, in a state where the band-shaped member is passed through the pass-through parts and the band-shaped member is curved at a predetermined curvature, the wing parts connect a surface part of the storage part to a surface part of the band-shaped member by a flat surface or a curved surface, so that the electronic device storage case never gives feeling of bulge to a user when it is attached to the body, results in excellent in design. Further, even when the electronic device storage case is covered with clothes, a bulge hardly occurs.

Further, the storage part has a surface part, and the surface part has a facing part which faces the electronic device stored in the storage part and connection parts which connect the facing part with surface parts of the wing parts, so that the connection parts connect the facing part with the wing parts to make it possible to prevent only the facing part from projecting from the wing parts.

Further, in a state where the electronic device is stored in the storage part, the connection parts tilt with respect to the facing part, so that the connection parts can smoothly connect the facing part with the wing parts.

Further, the surface part of the storage part and the surface parts of the wing parts are composed of the same member which extends from the surface part of the storage part to the surface parts of the wing parts, so that the surface part of the storage part and the surface parts of the wing parts can be formed into a continuous flat surface or curved surface. Furthermore, the surface part of the storage part and the surface parts of the wing parts can be easily formed.

Further, adjustment members for adjusting a positional relationship between the wing parts and the pass-through parts are provided between the wing parts and the pass-through parts, so that when gaps are generated between the wing parts and the pass-through parts, the adjustment members can keep the flat surface state or the curved surface state of the wing parts.

### BRIEF DESCRIPTION OF DRAWINGS

FIG. 1 is a front view illustrating a state where an electronic device is stored in an electronic device storage case according to an embodiment of the present invention;

FIG. 2 is a plan view illustrating the electronic device storage case according to an embodiment of the present invention (a state where no electronic device is stored);

FIG. 3 is a conceptual view in a state where the electronic device storage case according to an embodiment of the present invention (with an electronic device stored) is attached to a band-shaped member in an annular shape;

FIG. 4 (A) is a conceptual view illustrating a state where the electronic device storage case according to an embodiment of the present invention is attached to a user with a small waist, and (B) is a conceptual view illustrating a state where it is attached to a user with a large waist;

FIG. 5 is a perspective view of Modification Example 1 of the electronic device storage case according to an embodiment of the present invention;

FIG. 6 (A) is a partial conceptual view when the electronic device storage case in Modification Example 1 is mounted on the band-shaped member so that the storage part of the electronic device storage case is located on the outside of the body, and (B) is a partial conceptual view when the electronic device storage case is mounted on the band-shaped member so that the storage part is located on the inside of the body;

FIG. 7 is a perspective view of Modification Example 2 of the electronic device storage case according to an embodiment of the present invention;

FIG. 8 (A) is a partial conceptual view when the electronic device storage case in Modification Example 2 is mounted on the band-shaped member so that the storage part of the electronic device storage case is located on the outside of the band-shaped member, and (B) is a partial conceptual view when the electronic device storage case is mounted on the band-shaped member so that the storage part is located on the inside of the band-shaped member;

FIG. 9 is a perspective view of Modification Example 3 of the electronic device storage case according to an embodiment of the present invention; and

FIG. 10 is a perspective view of Modification Example 4 of the electronic device storage case according to an embodiment of the present invention.

### BEST MODE FOR CARRYING OUT THE INVENTION

Next, an electronic device storage case according to an embodiment of the present invention will be described referring to the drawings. Note that a smartphone (multifunctional cellular phone) will be exemplified in this embodiment as an example of the “electronic device” which is not limited to the smartphone but includes general electronic devices such as conventional cellular phone, portable terminal, mobile device and so on. Besides, the current electronic device generally has a structure in which its main body and liquid crystal screen are hard to be deformed, but an electronic device utilizing electronic paper, an electronic device having a touch panel or liquid crystal screen deformable like paper, and other electronic devices having a flexible structure are also within the scope of the present invention.

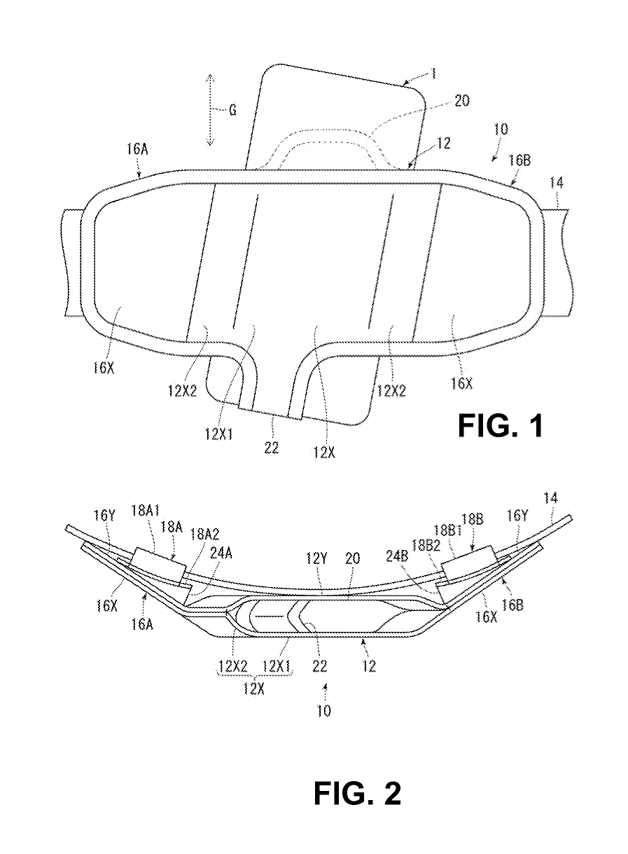

As illustrated in FIG. 1 and FIG. 2, an electronic device storage case 10 has a storage part 12 which stores a smartphone 1, a pair of wing parts 16A, 16B which are formed on both right and left sides of the storage part 12 for attaching the storage part 12 to a band-shaped member 14 such as a belt, and pass-through parts 18A, 18B which are formed at the wing parts 16A, 16B and through which the band-shaped member 14 is passed.

The storage part 12 is for storing the smartphone 1 and has an outside surface part 12X and an inside surface part 12Y. The outside surface part 12X of the storage part 12 has an outside facing part 12X1 which faces a predetermined face of the smartphone 1 stored in the storage part 12, and outside connection parts 12X2 which connect the outside facing part 12X1 with outside surface parts 16X of the wing parts 16A, 16B. The outside connection parts 12X2 tilt with respect to a thickness direction of the outside facing part 12X1 as seen from a plan direction (direction illustrated in FIG. 2) in a state where the smartphone 1 is stored in the storage part 12.

Note that the outside surface part 12X of the storage part 12 means a surface part located on the opposite side to the belt (body) side when the electronic device storage case 10 is put around the band-shaped member 14 such as a belt and attached to the body. Besides, the inside surface part 12Y of the storage part 12 means a surface part located on the belt (body) side when the electronic device storage case 10 is put around the band-shaped member 14 such as a belt and attached to the body.

At an upper portion of the inside surface part 12Y of the storage part 12, an upper side projecting part 20 projecting upward is formed. A predetermined face of the smartphone 1 stored in the storage part 12 can come into contact with the surface of the upper side projecting part 20. This makes it possible to prevent the smartphone 1 from being brought into direct contact with the band-shaped member 14 and the body so as to protect the smartphone 1.

On the other hand, at an upper portion of the outside surface part 12X of the storage part 12, any portion similar to the upper side projecting part 20 is not formed. Therefore, a portion on the outside surface part side of the smartphone 1 stored in the storage part 12 is greatly exposed to the outside to allow the smartphone 1 to be easily taken out by holding and pulling the exposed portion.

A bottom support part 22 is formed extending from a portion of a lower portion of the outside surface part 12X of the storage part 12 to a portion of a lower portion of the inside surface part 12Y. This makes it possible to support a bottom surface of the smartphone 1 stored in the storage part 12 from below to thereby prevent the smartphone 1 from falling. Further, in a state where the smartphone 1 is supported by the bottom support part 22, a portion on the lower end portion side of the smartphone 1 is exposed to the outside. This makes it possible for the user to push up the portion on the lower end portion side of the smartphone 1 stored in the storage part 12 with a finger and thus more easily take out the smartphone 1.

Here, the electronic device storage case 10 is structured to tilt at a predetermined tilt angle with respect to the vertical direction (an arrow G direction in FIG. 1) when it is put around the band-shaped member 14 and attached to the body. Therefore, the smartphone 1 stored in the storage part 12 is stored in a state of keeping the posture tilting at the predetermined angle. As a result, an upper end portion of the smartphone 1 is located at a position close to a hand of the user, thereby allowing the hand to easily reach and take out the smartphone 1.

The wing parts 16A, 16B are structured to be located on both right and left sides of the storage part 12 when the electronic device storage case 10 is put around the band-shaped member 14 and attached to the body. Each of the wing parts 16A, 16B is composed of the outside surface part 16X and an inside surface part 16Y. Note that the number of the wing parts 16A, 16B is not limited to two, but a structure provided with three or more wing parts and a structure provided with only one wing part are adoptable.

In a state where the band-shaped member 14 is passed through the pass-through parts 18A, 18B and is curved at a predetermined curvature, each of the wing parts 16A, 16B connects the outside surface part 12X of the storage part 12 to an outside surface part of the band-shaped member 14 by a flat surface or a curved surface. Therefore, when the electronic device storage case 10 is put around the band-shaped member 14 and attached to the body, a predetermined curved surface is formed from the outside surface part 12X of the storage part 12 to the outside surface part 16X of each of the wing parts 16A, 16B (see FIG. 2 to FIG. 4).

Here, the inside surface parts 16Y of the wing parts 16A, 16B and the inside surface part 12Y of the storage part 12 are composed of the same member. Further, the outside surface parts 16X of the wing parts 16A, 16B and the outside surface part 12X of the storage part 12 are composed of the same member.

The inside surface parts 16Y of the wing parts 16A, 16B are provided with the pass-through parts 18A, 18B respectively. The pass-through parts 18A, 18B have ring-shaped parts 18A1, 18B1, and mounting parts 18A2, 18B2 for mounting the ring-shaped parts 18A1, 18B1 to the inside surface parts 16Y of the wing parts 16A, 16B respectively. The ring-shaped parts 18A1, 18B1 are configured to allow the band-shaped member 14 to passed therethrough.

Note that the number of the pass-through parts 18A, 18B is not limited to two, but a structure provided with three or more pass-through parts is adoptable. This case includes a structure in which two or more pass-through parts are provided at one pass-through part 18A(18B) and a structure in which one or a plurality of pass-through parts are formed at the storage part 12.

Here, when the band-shaped member 14 is passed through the pass-through parts 18A, 18B so that the electronic device storage case 10 is put around the band-shaped member 14 and attached to the body so as to form the predetermined curved surface from the outside surface part 12X of the storage part 12 to the outside surface parts 16X of the wing parts 16A, 16B, a plane direction of the inside surface part 16Y of the wing part 16A, 16B is different from an out-of-plane direction of the mounting part 18A, 18B. For this reason, a predetermined gap is generated between the mounting part 18A, 18B and the inside surface part 16Y of the wing part 16A, 16B.

In order to fill the gap, each of adjustment members 24A, 24B is provided between the mounting part 18A2, 18B2 and the inside surface part 16Y of the wing part 16A, 16B. Each of the adjustment members 24A, 24B is formed of an elastic body such as rubber. Provision of the adjustment member 24A, 24B makes it possible to adjust and keep the positional relationship between the mounting part 18A2, 18B2 and the inside surface part 16Y of the wing part 16A, 16B, thereby keeping the predetermined curved surface from the outside surface part 12X of the storage part 12 to the outside surface part 16X of each of the wing parts 16A, 16B.

Note that the adjustment members 24A, 24B are not essential components. As a matter of course, a structure provided with no adjustment members 24A, 24B is adoptable.

Next, a manufacturing method of the electronic device storage case 10 in this embodiment will be schematically described.

(Formation of Outside Surface Part)

The outside surface part 12X of the storage part 12 and the outside surface parts 16X of the wing parts 16A, 16B are formed of the same member.

(Formation of Inside Surface Part)

The inside surface part 12Y of the storage part 12 and the inside surface parts 16Y of the wing parts 16A, 16B are formed of the same member.

(Overlay)

Here, the outside surface parts and the inside surface parts are preferably formed of the same member. Thus, the storage part 12 and the outside surface parts 16X and the inside surface parts 16Y of the wing parts 16A, 16B are overlaid with each other and they are sewn to each other. Therefore, at a boundary between the storage part 12 and each of the wing parts 16A, 16B, a stitching line is formed.

Note that it is preferable that an opening of the storage part 12 is maintained also in a state where the smartphone 1 is not stored in the storage part 12. To realize this, a shape-memory member such as cardboard may be embedded in the storage part 12.

(Formation of Pass-Through Part)

The mounting parts 18A2, 18B2 are sewn to the inside surface parts 16Y of the wing parts 16A, 16B. At this time, between the mounting parts 18A2, 18B2 and the inside surface parts 16Y, the ring-shaped parts 18A1, 18B1 are passed through and the adjustment members 24A, 24B are inserted. Note that the adjustment members 24A, 24B are in contact with the ring-shaped parts 18A1, 18B1 and therefore also serve as positioning functions for the ring-shaped parts 18A1, 18B1.

Through the above processes, the electronic device storage case 10 can be manufactured.

Next, the operation and effect of the electronic device storage case 10 in this embodiment will be described.

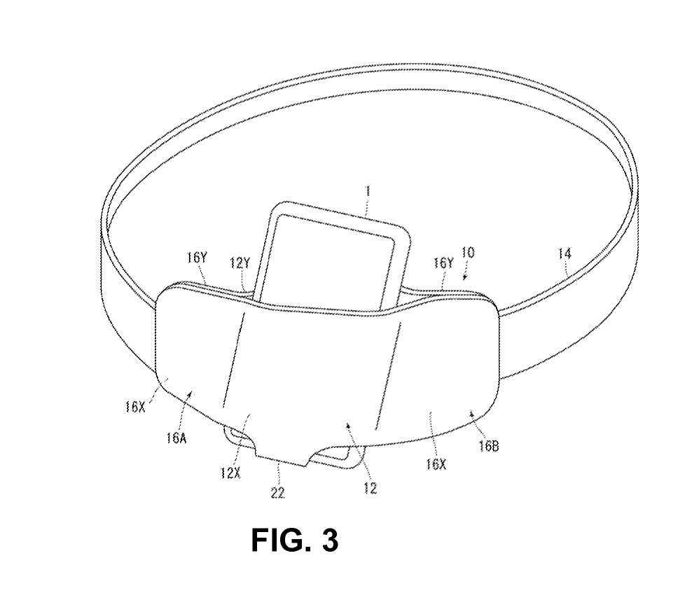

As illustrated in FIG. 1 and FIG. 3, the band-shaped member 14 such as a belt is passed through the ring-shaped parts 18A1, 18B1 of the two pass-through parts 18A, 18B, and the band-shaped member 14 is wrapped around the waist. Thus, the electronic device storage case 10 can be easily attached to the body.

Here, when the electronic device storage case 10 is put around the band-shaped member 14 and attached to the body, the predetermined curved surface (including a flat surface portion) is formed from the outside surface part 12X of the storage part 12 to the outside surface part 16X of each of the wing parts 16A, 16B. This prevents only the storage part 12 from awkwardly bulging outward, thus never giving unnatural feeling of bulge to the user. As a result, its design is improved even when the electronic device storage case 10 is attached to the body. Further, even when the electronic device storage case 10 is attached to the body and covered with clothes, any part of the clothes never awkwardly bulges outward.

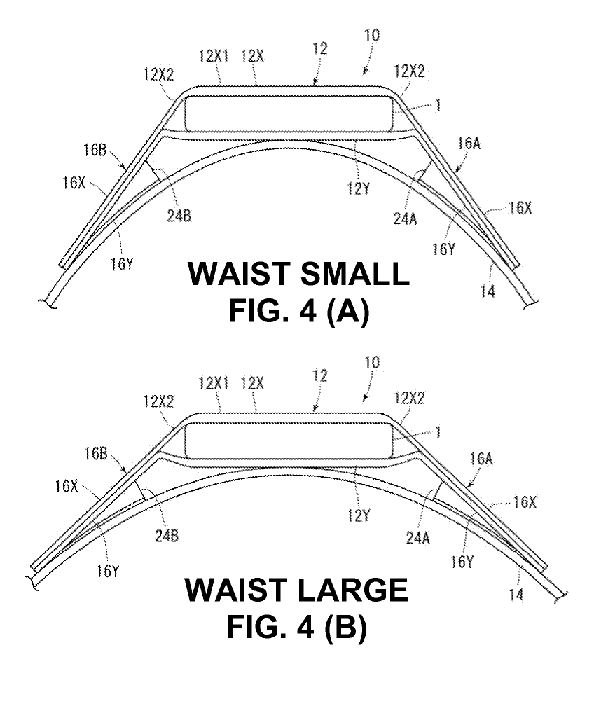

FIG. 4(A) is a view illustrating the bulging degree of the storage part 12 when a user with a small waist attaches the electronic device storage case 10 to his/her body. FIG. 4(B) is a view illustrating the bulging degree of the storage part 12 when a user with a large waist attaches the electronic device storage case 10 to his/her body.

As illustrated in FIG. 4, the bulging degree of the storage part 12 slightly differs depending on the waist size of the user, but a region from the storage part 12 to the band-shaped member 14 through the wing part 16A, 16B is basically formed of a flat surface or a curved surface. As described above, the operation of the flat surface or the curved surface composed of the storage part 12 and the wing part 16A, 16B can prevent only the storage part 12 from bulging outward.

In particular, the wing parts 16A, 16B of the electronic device storage case 10 have a function of suppressing bulge of the storage part 12 from the band-shaped member 14 and also function as mounting members of mounting the pass-through parts 18A, 18B for attaching the storage part 12 to the band-shaped member 14. As described above, imparting a plurality of functions to the wing parts 16A, 16B makes it possible to reduce the number of parts and achieve a simple configuration.

The wing parts 16A, 16B are provided on both right and left sides of the storage part 12, and the storage part 12 is located outside the band-shaped member 14 (opposite side to the body side), thereby making it possible to easily store the smartphone 1 into the storage part 12 and to easily take the smartphone 1 out of the storage part 12.

In particular, the outside surface part 12X of the storage part 12 has the outside facing part 12X1 which faces the smartphone 1 stored in the storage part 12 and the outside connection parts 12X2 which connect the outside facing part 12X1 with the outside surface parts 16X of the wing parts 16A, 16B so that the outside connection parts 12X2 connect the outside facing part 12X1 to the wing parts 16A, 16B, thereby making it possible to prevent only the outside facing part 12X1 from projecting from the wing parts 16A, 16B.

Further, since the outside surface part 12X of the storage part 12 and the outside surface parts 16X of the wing parts 16A, 16B are formed of the same member which extends from the outside surface part 12X of the storage part 12 to the outside surface parts 16X of the wing parts 16A, 16B, the outside surface part 12X of the storage part 12 and the outside surface parts 16X of the wing parts 16A, 16B can be formed into a continuous flat surface or curved surface. Furthermore, the outside surface part 12X of the storage part 12 and the outside surface parts 16X of the wing parts 16A, 16B can be easily formed. This also applies to the relation between the inside surface part 12Y of the storage part 12 and the inside surface parts 16Y of the wing parts 16A, 16B.

Further, the adjustment members 24A, 24B for adjusting the positional relationship between the wing parts 16A, 16B and the pass-through parts 18A, 18B are provided between the wing parts 16A, 16B and the pass-through parts 18A, 18B respectively, so that when gaps are generated between the wing parts 16A, 16B and the pass-through parts 18A, 18B, the adjustment members 24A, 24B can keep the flat surface state or the curved surface state of the wing parts 16A, 16B.

In particular, the adjustment members 24A, 24B are formed of an elastic body such as rubber and are therefore freely elastically deformed according to the dimensions of the gaps between the wing parts 16A, 16B and the pass-through parts 18A, 18B and the action of an external force. Thus, the elastic deformation of the adjustment members 24A, 24B can absorb the dimensional error and the external force, leading to an increase in degree of freedom of design.

As described above, using the electronic device storage case 10 in this embodiment allows the smartphone 1 to be surely and easily stored and taken out without deteriorating the line of clothes of the user. Therefore, it is possible to more surely prevent damage to the smartphone 1 and loss of the smartphone 1 due to falling as compared with the case where the smartphone 1 is stored in a pocket or the like. Further, storage of the smartphone 1 in the electronic device storage case 10 and attaching of the electronic device storage case 10 to the body makes the user walk more easily than in the case where the smartphone 1 is stored in the pocket or the like.

### Various Modifications

Next, modifications will be described. Note that description of the same configuration as that in the above embodiment will be appropriately omitted in the following modifications.

### Modification Example 1

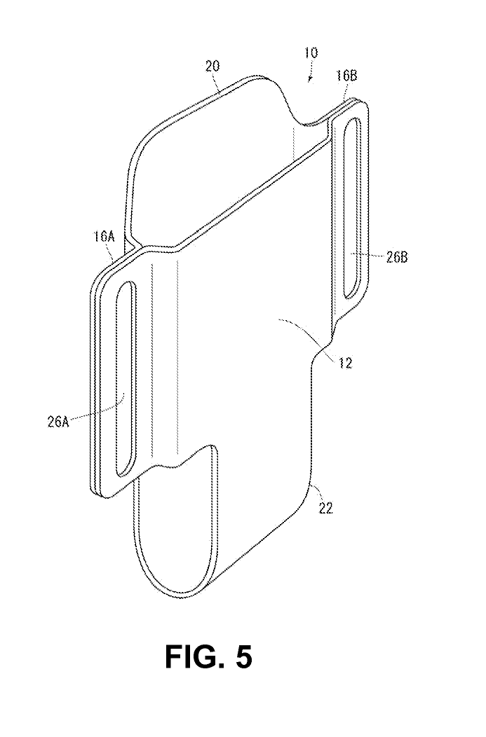

As illustrated in FIG. 5, pass-through parts in Modification Example 1 may be composed of only long holes 26A, 26B directly formed in the respective wing parts 16A, 16B. In Modification Example 1, the electronic device storage case 10 can be attached to the body with the band-shaped member 14 such as a belt passed through the long holes 26A, 26B.

According to Modification Example 1, the pass-through parts can be easily provided only by forming the long holes 26A, 26B in the wing parts 16A, 16B. Further, it is possible to reduce the number of parts and reduce the manufacturing cost.

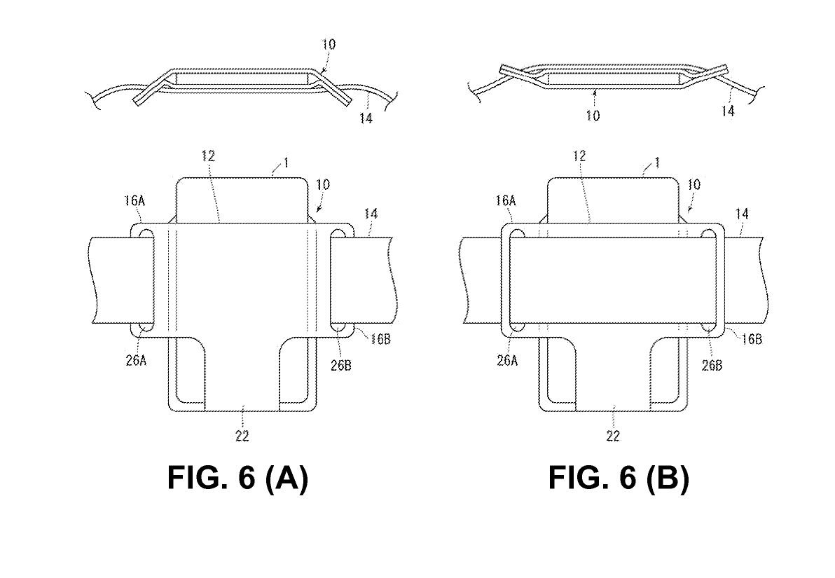

Further, in Modification Example 1, it is possible to attach the storage part 12 so that it is located on the outside of the band-shaped member 14 (on the opposite side to the body side) (see FIG. 6(A)) and also possible to attach the storage part 12 so that it is located on the inside of the band-shaped member 14 (on the body side) (see FIG. 6(B)). In an aspect in which the storage part 12 is located on the inside of the band-shaped member 14, the problem as in Patent Document 2 may occur, but the wing parts 16A, 16B are formed on both right and left sides of the storage part 12 to smoothly connect the storage part 12 and the band-shaped member 14. This can prevent the storage part 12 from strangely projecting from the band-shaped member 14. Further, the existence of the wing parts 16A, 16B reinforces the opening of the storage part 12 and thus maintains the shape of the opening. As a result, it becomes more easy to store or take out the smartphone 1.

### Modification Example 2

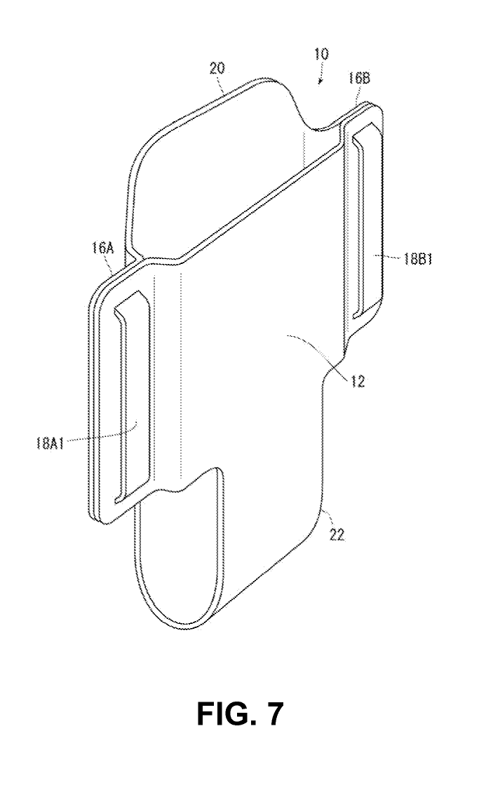

As illustrated in FIG. 7, as pass-through parts in Modification Example 2, both end portions of the electronic device storage case 10 are composed of only the ring-shaped parts 18A1, 18B1 directly sewn or mounted to the wing parts 16A, 16B. In short, no mounting parts are required.

According to Modification Example 2, since no mounting parts are required, the number of parts can be reduced. Thus, the manufacturing cost can be reduced.

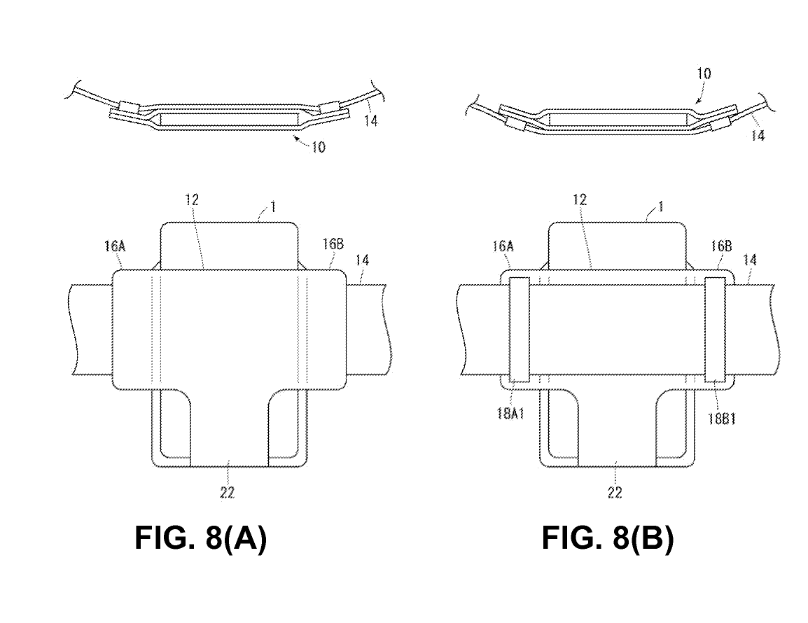

Also in Modification Example 2, it is possible to attach the storage part 12 so that it is located on the outside of the band-shaped member 14 (on the opposite side to the body side) (see FIG. 8(A)) and also possible to the storage part 12 so that it is located on the inside of the band-shaped member 14 (on the body side) (see FIG. 8(B)). In an aspect in which the storage part 12 is located on the inside of the band-shaped member 14, the problem as in Patent Document 2 may occur, but the problem can be solved because of the same reason as that in Modification Example 1.

### Modification Example 3

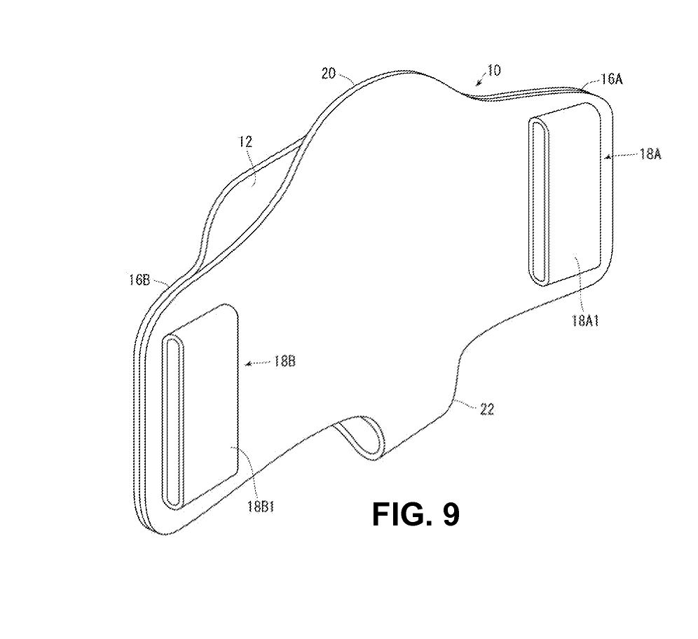

As illustrated in FIG. 9, pass-through parts in Modification Example 3 are composed of only the ring-shaped parts 18A1, 18B1 which have outer peripheral surfaces having predetermined regions directly sewn or attached to the respective wing parts 16A, 16B. In short, no mounting parts are required.

According to Modification Example 3, since no mounting parts are required, the number of parts can be reduced. Thus, the manufacturing cost can be reduced.

### Modification Example 4

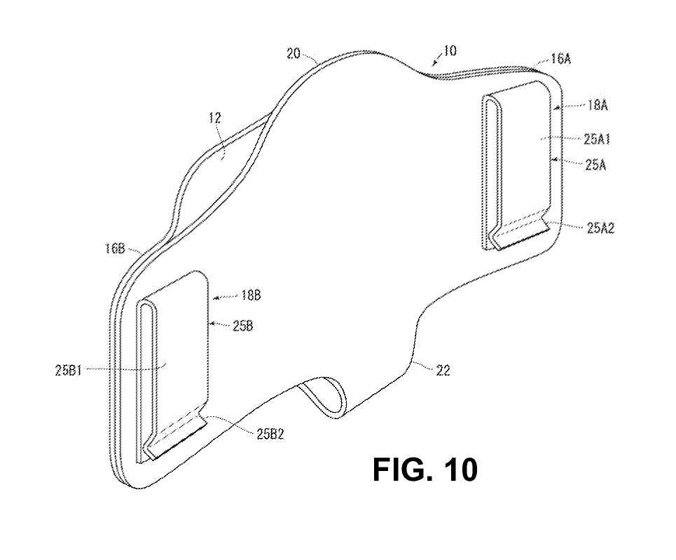

As illustrated in FIG. 10, pass-through parts 18A, 18B in Modification Example 4 are composed of clip parts 25A, 25B made of metal or plastic (including silicon) mounted on the respective wing parts 16A, 16B. The clip parts 25A, 25B have elastic parts 25A1, 25B1 holding the band-shaped member 14 from both sides in its thickness direction. At tip end portions of the elastic parts 25A1, 25B1, pressure concentrating parts 25A2, 25B2 are formed which press against the band-shaped member 14.

According to Modification Example 4, the electronic device storage case 10 can be attached to the band-shaped member 14 by putting the elastic parts 25A1, 25B1 of the clip parts 25A over the band-shaped member 14 from above the band-shaped member 14 while the user is keeping the band-shaped member 14 attached thereto without removing it, in other words, while the band-shaped member 14 keeps its annular shape. This eliminates the necessity to remove the band-shaped member 14 once when the electronic device storage case 10 is attached to the band-shaped member 14, thereby facilitating the mounting work of the electronic device storage case 10.

In particular, the pressure concentrating parts 25A2, 25B2 apply a predetermined pressure to the band-shaped member 14, thereby making it possible to prevent the clip parts 25A, 25B from unexpectedly withdrawing from the band-shaped member 14.

Note that the present invention is not limited to the contents described in this embodiment and modification examples. Differences such as changes in design matter made by persons skilled in the art, which include the spirit of the present invention, are included in the present invention.

### EXPLANATION OF CODES

1 smartphone (electronic device)
10 electronic device storage case
12 storage part
12X outside surface part (surface part of storage part)
12X1 outside facing part (facing part of storage part)
12X2 outside connection part (connection part of storage part)
14 band-shaped member
16A wing part
16B wing part
18A pass-through part
18B pass-through part
24A adjustment member
24B adjustment member
25A clip part
25B clip part

1. An electronic device storage case, comprising:
a storage part which stores an electronic device; and
wing parts which are formed on both sides of the storage part and attach the storage part to a band-shaped member,
wherein the wing parts are formed with pass-through parts through which the band-shaped member is passed.

2. The electronic device storage case according to claim 1, wherein in a state where the band-shaped member is passed through the pass-through parts and the band-shaped member is curved at a predetermined curvature, the wing parts connect a surface part of the storage part to a surface part of the band-shaped member by a flat surface or a curved surface.

3. The electronic device storage case according to claim 2, wherein the surface part of the storage part has a facing part which faces the electronic device stored in the storage part and connection parts which connect the facing part with surface parts of the wing parts.

4. The electronic device storage case according to claim 3, wherein in a state where the electronic device is stored in the storage part, the connection parts tilt with respect to the facing part.

5. The electronic device storage case according to claim 1, wherein the surface part of the storage part and the surface parts of the wing parts are composed of the same member which extends from the surface part of the storage part to the surface parts of the wing parts.

6. The electronic device storage case according to claim 1, further comprising: adjustment members, which are provided between the wing parts and the pass-through parts, for adjusting a positional relationship between the wing parts and the pass-through parts.
